(19) United States
(12) Patent Application Publication
(10) Pub. No.: US 2026/0349124 A1
(43) Pub. Date: Nov. 5, 2026

(54) SEMICONDUCTOR DETECTOR MODULE, CHARGE PUMP CIRCUIT AND PORTABLE MEASUREMENT DEVICE

(71) Applicant: KETEK GmbH Halbleiter- und Reinraumtechnik, Muenchecn (DE)

(72) Inventors: Werner Buttler, Essen (DE); Tobias Michel, Muenchen (DE); Peter Iskra, Neubiberg (DE); Florian Wiest, Muenchen (DE)

(21) Appl. No.: 19/197,503

(22) Filed: May 2, 2025

(51) Int. Cl. G01T 1/24; G01N 23/223; H02M 3/04; H10F 30/292; H10F 39/90; H10F 77/00; H10F 77/50

(52) U.S. Cl. CPC G01T 1/24; G01N 23/223; H02M 3/04; H10F 30/292; H10F 39/90; H10F 77/50; H10F 77/933; G01N 2223/301

(57) ABSTRACT

In an embodiment a semiconductor detector module includes at least one semiconductor detector unit and a DC-DC converter unit configured to convert a low voltage provided at a low voltage input to a at least one high voltage for the at least one semiconductor detector unit, wherein the DC-DC converter unit comprises at least one regulator configured to control an output of the DC-DC converter unit and to provide the high voltage with a constant value.

### TECHNICAL FIELD

The present disclosure relates to a semiconductor detector module, a charge pump circuit and a portable measurement device.

### SUMMARY

Embodiments provide an improved semiconductor detector module which in particular can be supplied with a low voltage. Further embodiments provide an improved charge pump circuit which may be used in a semiconductor detector module described herein. Yet other embodiments provide a portable measurement device which uses a semiconductor detector module described herein.

According to at least one embodiment, the semiconductor detector module comprises at least one semiconductor detector unit. The at least one semiconductor detector unit is configured to detect electromagnetic radiation, which may in particular be X-rays. The semiconductor detector unit is in particular configured to generate a detector signal corresponding to detected electromagnetic radiation. For example, the semiconductor detector unit comprises a silicon drift detector or a semiconductor detector having a PIN structure.

According to at least one embodiment, the semiconductor detector module comprises a DC-DC converter unit configured to convert a low voltage provided at a low voltage input of the DC-DC converter unit to at least one high voltage for the at least one semiconductor detector unit. In particular, the semiconductor detector unit is supplied with one or more high voltages, for example three high voltages, during operation.

For example, the DC-DC converter unit comprises exactly one low voltage input to which the low voltage can be applied, for example by an external power source. The low voltage may be a voltage having a value of between −5 V and 5 V, inclusive. The at least one high voltage may have a value of at least −10 V and at most −2000 V, depending on the detector unit.

In a specific example, the DC-DC converter unit receives one low voltage at the low voltage input of 5 V. In this example this DC-DC converter unit may provide three high voltages wherein a first high voltage is between −10 V and −30 V, a second high voltage is between −110 V and −180 V and a third high voltage is between −50 V and −100 V. These high voltages may be applied to the semiconductor detector unit to operate the semiconductor detector unit. In the specific example, the semiconductor module may comprise exactly one semiconductor detector unit.

For example, the DC-DC converter unit may comprise at least one charge pump for converting the low voltage to the at least one high voltage. The charge pump may comprise several stages, depending on the value or the magnitude of the high voltage to be achieved.

According to at least one embodiment, the DC-DC converter unit comprises at least one regulator configured to control an output of the DC-DC converter unit at which the high voltages are supplied. In particular, the output of the DC-DC converter unit is controlled such that the high voltage is provided with a constant value. Here and in the following a “constant value” in particular means that the high voltage value has fluctuations below 1% or preferably below 0.5% or further preferably below 0.25% of the target constant value.

In particular, regulation loop or control loop may be formed in the DC-DC converter unit by the regulator such that a voltage conversion of the low voltage to the one high voltage can be controlled and regulated so that a constant output value can be achieved. For example, the high voltage output by the DC-DC converter unit is used as an input for the regulator to achieve the control loop.

For example, the regulator is a regulator comprising a proportional portion, an integral portion and a differential portion. In this case, the regulator in particular is a PID regulator.

In at least one embodiment, the semiconductor detector module comprises at least one semiconductor detector unit and a DC-DC converter unit configured to convert a low voltage provided at a low voltage input to the at least one high voltage for the at least one semiconductor detector unit. The DC-DC converter unit comprises at least one regulator configured to control an output of the DC-DC converter unit to provide the high voltage with a constant value.

The semiconductor detector module is based on the following technical considerations. Depending on a detector material and application, semiconductor detectors may require a high voltage supply of typically a range between 10 V up to several thousand volts. For example, if the semiconductor detector is a silicon drift detector, three high voltages may be required. Typical values for the three voltages are between −10 V and −30V, between 110 V and −180 V and between −50 and −100 V, respectively. Commonly, these three high voltages are generated outside of the corresponding detector module which comprises the silicon drift detector and are fed to the detector via contact pins. However, this may require fulfilment of safety standards which are, for example, defined for components operated with voltages above 50 V. Furthermore, sufficient clearage and creepage distances have to be considered for each high voltage supply. Fulfilling these safety requirements may create additional costs and limit flexibility in application. Therefore, integration of the high voltage supply in the detector module is advantageous. However, such an integration may require a precise and stable voltage regulation.

The semiconductor detector module described herein is based on the idea of integrating a DC-DC converter unit to supply high voltages for the semiconductor detector unit inside the detector module. Furthermore, the DC-DC converter unit comprises a regulator via which the high voltages provided by the DC-DC converter unit can be provided with a constant value. It is thus advantageously possible to externally supply the semiconductor detector module purely by one or more low voltages. Thus, safety requirements which need to be fulfilled for electrical safety of the semiconductor detector module are less restrictive than in the case where high voltages are externally supplied. This both improves handling of the semiconductor detector module in application and reduces costs.

According to at least one embodiment of the semiconductor detector module, the DC-DC converter unit comprises at least one charge pump circuit. In particular, the charge pump circuit comprises an oscillator configured to provide a clock signal. The charge pump circuit preferably further comprises a clock buffer configured to amplify the clock signal. The charge pump circuit preferably further comprises the regulator configured to provide an upper control voltage and a lower control voltage as supply voltages to the clock buffer. In particular, the at least one charge pump circuit comprises at least one charge pump configured to convert the low voltage into high voltage. The regulator is in particular configured to adjust the upper control voltage and the lower control voltage such that the charge pump provides the high voltage with the constant value. For example, the regulator receives the high voltage output by the charge pump as an input to adjust the upper control voltage and the lower control voltage, thus in particular forming a control loop.

For example, the charge pump circuit receives the low voltage provided at the low voltage input of the DC-DC converter unit as an input. This low voltage is in particular converter to the high voltage by the charge pump.

For example, the oscillator is configured to drive the charge pump by providing the clock signal. The clock signal is amplified by the buffer signal to provide an amplified clock signal, for example. In particular, the amplified clock signal is input in the charge pump for driving the charge pump. Amplification of the clock signal performed by the clock buffer is in particular controlled and regulated by the regulator by means of providing the upper control voltage and the lower control voltage. Thus, it is advantageously possible to adjust the amplified clock signal driving the charge pump by the regulator such that the high voltage is output with a constant value.

In case that a plurality of high voltages are supplied by the DC-DC converter unit, the DC-DC converter unit comprises a plurality of charge pump circuits and a plurality of charge pumps. Each of these charge pump circuits in particular comprises the oscillator, the clock buffer, the regulator and the charge pump. Preferably, for each high voltage to be output by the DC-DC converter unit, one charge pump circuit is provided in the DC-DC converter unit. This advantageously allows to control the output of each charge pump circuit individually by the corresponding regulator.

Common regulated charge pumps comprise a charge pump, an oscillator for driving the charge pump, and a comparator which regulates the output of the charge pump. The charge pump may be formed with several stages, wherein the number of stages defines the output voltage which can be achieved. Control of the output voltage is carried out by the comparator which is configured to switch a connection between the oscillator and the charge pump, for example by controlling a switch. The comparator is configured to compare the output voltage of the charge pump with a reference voltage. If the output voltage falls below the reference voltage, the connection between the oscillator and the charge pump is closed, otherwise the connection is opened. The comparator further comprises a hysteresis which causes an oscillation of the output voltage of the charge pump between two thresholds. Due to these two thresholds, the output voltage of the charge pump is not constant in the above-mentioned way, but comprises for example a sawtooth pattern. Thereby a frequency of the sawtooth pattern may interfere with signals of the semiconductor detector unit and signals of a signal chain of processing the detector signals so that the efficiency of the semiconductor detector module decreases.

The charge pump circuit described herein makes use of the idea of providing a clock buffer between the oscillator and the charge pump. By the clock buffer, the oscillator signal, i.e. the clock signal, can be amplified. The amplification of the clock buffer, and thus the amplified clock signal, is controlled and regulated by the regulator which is particular is a PID regulator.

The regulator provides supply voltages for the clock buffer. The supply voltages are the upper control voltage and the lower control voltage. The regulator is configured to adjust the upper control voltage and the lower control voltage according to the high voltage provided at an output of the charge pump. It is advantageously possible to adjust the upper control voltage and the lower control voltage such that the charge pump can output the high voltage with a constant value.

In particular, compared to the comparator used in common charge pump circuits, the regulator provides a smoother regulation. This means in particular that the sawtooth pattern present at the output of the common charge pumps can be avoided in the charge pump circuit described herein. Thus, disturbing frequencies emerging from the DC-DC converter unit can be reduced and interference with the signal chain processing the detector signal can be reduced. Consequently, the efficiency of the semiconductor detector module can advantageously be increased.

According to at least one embodiment, the regulator is configured to adjust the value of the high voltage, in particular provided by the charge pump circuit, by adjusting a difference between the upper control voltage and the lower control voltage. For example, if the difference between the upper control voltage and the lower control voltage increases, the constant value of the high voltage also increases. For example, if the difference between the upper control voltage and the lower control voltage increases, the amplification provided to the clock signal by the clock buffer also increases.

According to at least one embodiment, the semiconductor detector module further comprises a control unit configured to control the regulator to adjust the value of the high voltage according to a load connected to the charge pump circuit. In particular, the load is connected to the DC-DC converter unit comprising the charge pump circuit. For example, the load is determined by the semiconductor detector unit.

The load may comprise at least one resistance and/or at least one capacity. It is possible that the load determined by the semiconductor detector unit change over time during operation of the semiconductor detector unit, for example due to temperature drifts or the like. For example, if the semiconductor detector unit is started, the loads are different from an ongoing continuous operation. A specific example illustrating the loads occurring in operation of a silicon drift detector will be described below.

It is advantageously possible to adapt the regulator to adjust the supply voltages of the clock buffer such that the constant value of the high voltage provided by each charge pump circuit is adjusted according to the corresponding load determined by the semiconductor detector unit. Thus, the DC-DC converter unit described herein can adjust its output if the load changes due to environmental influences or due to different operation modes of the semiconductor detector unit. Advantageously this adjustment may not require external parts for analyzing the loads or the like. Further advantageously, it is not necessary to adjust the external voltage supply for the detector module in case that the loads change.

According to at least one embodiment of the semiconductor detector module comprising a control unit, the control unit is further configured to adjust, for example, the upper control voltage and/or the lower control voltage in accordance with the value of the high voltage determined according to the load. In other words, the control unit is configured to adjust amplification of the clock buffer.

It is alternatively of additionally possible that the control unit is configured to adjust the frequency of the oscillator.

Furthermore, the control unit may be additionally or alternatively configured to control and/or synchronize a plurality of charge pump circuits, in particular in the case that the DC-DC converter unit is configured to provide a plurality of high voltages. High voltages provided by different charge pump circuits may be adjusted and controlled independently of one another by the control unit. Preferably, in case that the DC-DC converter unit comprises a plurality of charge pump circuits, it is possible that the DC-DC converter unit comprises one control unit configured to control, synchronize and orchestrate the plurality of charge pump circuits such that each charge pump circuits provides a stable high voltage of a predetermined constant value.

Preferably, the control unit comprises a data interface by which the control unit may communicate with external devices such as computers or the like. For example, operation data for the semiconductor detector module may be provided to the control unit by the data interface. Preferably, the data interface is a digital interface.

According to at least one embodiment, the semiconductor detector unit comprises exactly one semiconductor detector unit which is configured to be supplied with three high voltages. In other words, the at least one charge pump circuit comprises a first charge pump circuit, a second charge pump circuit and a third charge pump circuit.

In this case, the DC-DC converter unit in particular comprises a first charge pump circuit, a second charge pump circuit and a third charge pump circuit configured to provide a first high voltage, a second high voltage, and a third high voltage, respectively.

Preferably, each of the charge pump circuits comprises components, functionality and effects described above.

For example, the control unit controls and synchronizes the charge pump circuits. For example, the exactly one semiconductor detector unit is a silicon drift detector.

According to at least one embodiment, the semiconductor detector module comprises a plurality of semiconductor detector units, each configured to be supplied with three voltages. In other words, the at least one semiconductor detector unit comprises a plurality of semiconductor detector units.

In particular in this case the DC-DC converter unit comprises a plurality of first charge pump circuits, a plurality of second charge pump circuits and a plurality of third charge pump circuits configured to supply first voltages, second voltages and third voltages, respectively, to each of the semiconductor units.

Preferably, each of the charge pump circuits comprises components, functionality and effects described above.

It is advantageous that each of the charge pump circuits is controlled by the control unit. For example, the control unit is configured to control each charge pump circuit such that each charge pump circuit provides an adjustable and constant high voltage for the corresponding semiconductor detector unit.

According to at least one embodiment of the semiconductor detector module comprising a plurality of semiconductor detector units, the control unit is configured to adjust each of the first, second and third voltages according to a corresponding load provided by the assigned semiconductor detector unit. It is thus possible to operate all semiconductor detector units with an adjusted and constant high voltage.

According to at least one embodiment of the semiconductor detector module, the at least one semiconductor detector unit and the DC-DC converter unit are integrated in a common module housing. The semiconductor detector module is externally electrically supplied exclusively by the low voltage. By integrating the DC-DC converter unit and the semiconductor detector unit in the common module housing it is advantageously possible to provide the semiconductor detector module in a compact manner. For example, in this case the semiconductor detector module may comprise only a limited number of inputs. For example, the inputs are limited to the low voltage input and, optionally, to the data interface of the control unit. It is thus advantageously possible to integrate the semiconductor detector module comparably easily in applications.

According to at least one embodiment of the semiconductor detector module, the at least one semiconductor detector unit and the DC-DC converter unit are arranged in distinct housings and the semiconductor detector module is externally electrically supplied exclusively by the low voltage.

According to at least one embodiment, each semiconductor detector unit comprises a silicon drift detector. In particular, each silicon drift detector is supplied with three high voltages.

The silicon drift detector for example comprises a front side and a back side opposite to the front side. At the front side, the silicon drift detector may comprise an anode at which a detector signal is generated. Furthermore, a plurality of drift rings may be provided at the front side of the silicon drift detector. The drift rings are concentrically arranged around the anode. Furthermore, at least one front guard ring may be provided at the front side enclosing the plurality of drift rings in view of the front side.

At a first drift ring, closest to the anode, the first high voltage provided by the DC-DC converter unit may be applied to the silicon drift detector. At a last drift ring closest to the at least one guard ring, the second high voltage provided by the DC-DC converter unit may be applied to the silicon drift detector. The front guard ring may be connected to ground potential. Preferably, however, the front guard ring is not connected to a potential but is designed as a so-called floating guard ring.

At the back side, the third high voltage provided by the DC-DC converter unit may be applied to the radiation window region of the silicon drift detector. In the radiation window region electromagnetic radiation, in particular X-rays, to be detected by the silicon drift detector may enter the silicon drift detector. Furthermore, the silicon drift detector may comprise a back guard ring at the back side enclosing the window region in view of the back side. The back guard ring may be also connected to ground potential. Preferably, however, the back guard ring is not connected to a potential but is designed as a so-called floating guard ring. The front and back guard rings are in particular used for a defined potential reduction towards the edge of the substrate down to zero.

By applying all three voltages to the silicon drift detector, a lateral and vertical drift field is generated in a semiconductor body of the silicon drift detector with respect to the silicon surface. The semiconductor body may be n-doped and based on a silicon material system. If electromagnetic radiation enters the semiconductor body, free charges, in particular electrons, are generated in the body and guided to the anode by the drift field. At the anode, the free charges are collected and the detector signal is generated. In order to operate the silicon drift detector as intended, the first to third high voltages have to be precisely controlled by the DC-DC converter unit.

According to at least one embodiment, the regulator is configured to be operated as a PID regulator.

According to at least one embodiment, the DC-DC converter unit is integrated in an application-specific integrated circuit, ASIC for short. Alternatively, the DC-DC converter unit may be integrated in any suitable electronic component respectively circuit.

Furthermore, a charge pump circuit is specified. The charge pump circuit may in particular be used in a semiconductor detector module described herein. This means that all features disclosed for the charge pump circuit are also disclosed for the semiconductor detector module and vice versa.

According to at least one embodiment, the charge pump circuit is configured to convert a low voltage to a high voltage and comprises an oscillator configured to provide a clock signal, a clock buffer configured to amplify the clock signal and a regulator configured to provide an upper control voltage and a lower control voltage as supply voltages to the clock buffer. The charge pump circuit further comprises at least one charge pump configured to convert the low voltage to the high voltage. In particular, the regulator is configured to adjust the upper control voltage and the lower control voltage such that the charge pump is configured to provide the high voltage with a constant value.

In particular, the regulator is a PID regulator with a comparably smooth regulation. Therefore, it is advantageously possible to adjust the upper control voltage and the lower control voltage such that the charge pump circuit can output the high voltage with a constant value in accordance with the above-mentioned manner.

According to at least one embodiment of the charge pump circuit, the regulator is configured to adjust the value of the high voltage by adjusting a difference between the upper control voltage and the lower control voltage. If, for example, the difference between the upper control voltage and the lower control voltage increases, the constant value of the high voltage also increases. This relation in particular implies that a load to which the charge pump circuit is connected is constant.

According to at least one embodiment of the charge pump circuit, the charge pump circuit comprises or is coupled to a control unit configured to control the regulator to adjust the value of the high voltage according to a load connected to an output of the charge pump circuit. For example, the load is determined by an application of the charge pump circuit, for example by a detector unit to which the charge pump circuit is connected.

According to at least one embodiment of the charge pump circuit comprising a control unit, the charge pump circuit and the control unit are integrated in a single electronic component having a data interface and a single low voltage input. It is possible that further charge pump circuits are integrated in the electronic component. That is, the electronic component may comprise a plurality of charge pump circuits. For example, the electronic component comprises the DC-DC converter unit which comprises the plurality of charge pump circuits. The electronic component may be an application-specific integrated circuit, ASIC for short.

Furthermore, a portable measurement device for analyzing a sample by means of X-ray fluorescence is specified. The portable measurement device may comprise a semiconductor detector module described herein. This means that all features disclosed for the portable measurement device are also disclosed for the semiconductor detector module and vice versa.

According to at least one embodiment, the portable measurement device comprises an X-ray source configured to irradiate the sample with X-rays. The portable measurement device further comprises a semiconductor detector module described herein configured to detect fluorescence radiation radiated by the sample in response to being exposed to X-rays and to generate a corresponding detector signal. Furthermore, the portable measurement device comprises a calculation unit comprising a digital signal processor configured to analyze the detector signal to measure the sample.

In particular, the portable measurement device can be supplied with a low voltage, for example from a battery, since the semiconductor detector module can be operated with a low voltage by using the DC-DC converter unit. Furthermore, the X-ray source may be an X-ray tube comprising a voltage cascade which also may be supplied by the low voltage. Thus, it is advantageously possible to form the portable measurement device with a comparable compact housing including a battery or the like. Thus, no complex external voltage supply is necessary, and the portable measurement device can easily be used in different applications. Preferably, the calculation unit comprises a data interface, for example a wireless data interface, by which the evaluated detector signal can be output.

### BRIEF DESCRIPTION OF THE DRAWINGS

Further advantages and advantageous embodiments and further developments of the method and the switching device described will become apparent from the following exemplary embodiments shown in connection with schematic drawings. Identical elements, elements of the same kind or elements having the same effect are provided with the same reference signs in the figures. The figures and the proportions of the elements shown in the figures are not to be regarded as true to scale. Rather, individual elements may be shown exaggeratedly large for better representability and/or for better comprehensibility.

In the figures:

FIG. 1 shows a schematic representation of semiconductor detector module described herein according to a first exemplary embodiment;

FIG. 2 shows a schematic representation of a semiconductor detector unit used in the semiconductor module according to the first exemplary embodiment;

FIGS. 3A and 3B show a detailed representation of the semiconductor detector unit of FIG. 2 illustrating loads determined by the semiconductor detector unit;

FIG. 4 shows a charge pump circuit according to an exemplary embodiment;

FIGS. 5A and 5B shows a diagram illustrating outputs of the charge pump circuit of FIG. 4 as a function of time for providing different supply voltages of the clock buffer;

FIG. 6 shows a modified charge pump circuit according to a comparative example;

FIGS. 7A and 7B shows a diagram illustrating an output of the charge pump circuit of FIG. 4 as a function of time;

FIG. 8 shows a schematic representation of semiconductor detector module described herein according to a second exemplary embodiment; and

FIG. 9 shows a block diagram illustrating a portable measurement device described herein according to an exemplary embodiment.

### DETAILED DESCRIPTION OF ILLUSTRATIVE EMBODIMENTS

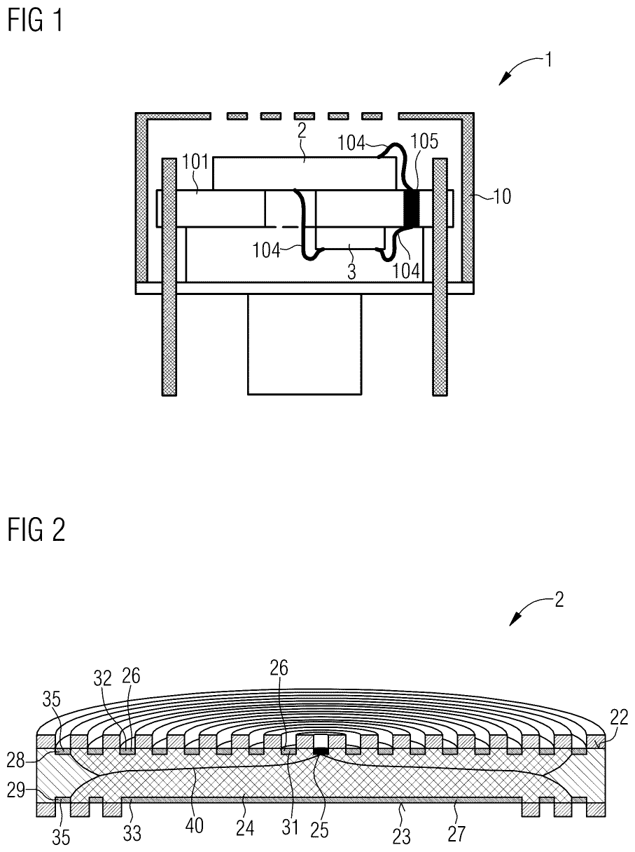

The semiconductor detector module 1 according to the first exemplary embodiment shown in FIG. 1 comprises a semiconductor detector unit 2 and a DC-DC converter unit 3. In the present exemplary embodiment, the semiconductor detector unit 2 comprises a silicon drift detector and the DC-DC converter unit 3 comprises an application-specific integrated circuit, ASIC for short.

As shown in FIG. 2, the semiconductor detector unit 2 comprises a semiconductor body 24 which is preferably based on a silicon material system and is preferably n-doped. An anode 25 is arranged on a front side 22 of the semiconductor detector unit 2. Further, at the front side 22 a plurality of drift rings 26 is arranged. The drift rings 26 are arranged concentrically around the anode 25. Furthermore, a front guard ring 28, which is concentrically arranged around the drift rings 26 and encloses the drift rings 26, is arranged on the front side 22.

At a back side 23 of the semiconductor detector unit 2, a radiation window region 27 is arranged through which electromagnetic radiation, in particular X-rays, may enter the semiconductor body 24. Furthermore, a back side guard 29 ring opposing the front side guard ring 28 is arranged at the back side 23 of the semiconductor detector unit 2.

During intended operation of the semiconductor detector unit 2, a first high voltage 31 is applied to the first drift ring 26 closest to the anode 25. Furthermore, a second high voltage 32 is arranged at the drift ring 26 closest to the front guard rings 28. Furthermore, a third high voltage 33 is applied to the radiation window region 27 at the back side 23. The guard rings 28, 29 can be connected to ground 35 or can be left floating during intended operating. The guard rings 28, 29 are used for a defined potential reduction towards the edge of the semiconductor body 24 down to zero.

A drift field 40 is formed inside the semiconductor body 24 by applying the high voltages 31, 32, 33. If electromagnetic radiation, in particular X-ray radiation, enters the semiconductor body 24, free charge carriers, in particular electrons, are generated that are guided to the anode 25 by the drift field 40. At the anode 25, the free charge carriers and the detector signal are generated.

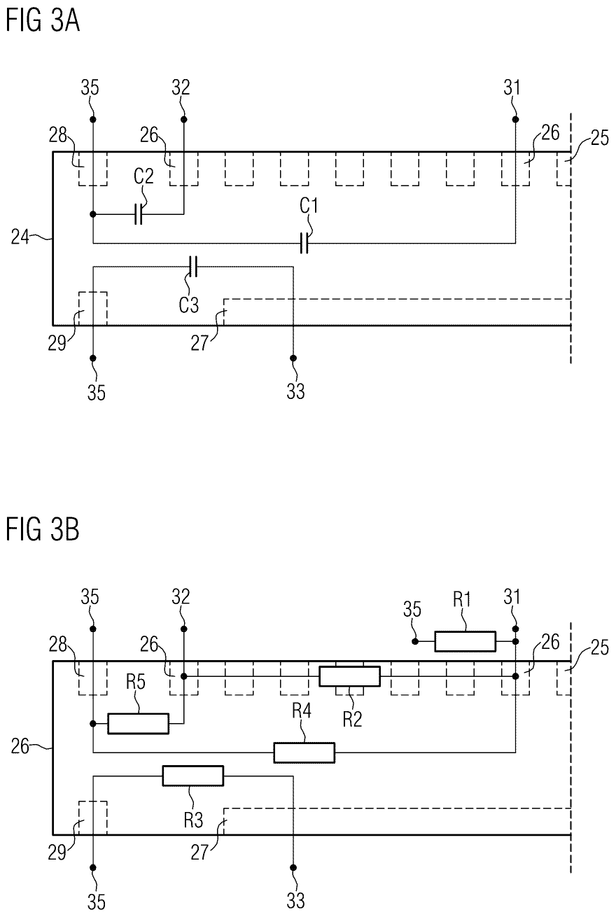

FIGS. 3A and 3B illustrate loads that are determined by the semiconductor detector unit 2 during operation of the semiconductor detector module 1. The load determined by the semiconductor detector unit 2 comprises capacitances C1 to C3 and resistances R1 to R5.

As illustrated in FIGS. 3A and 3B, the first high voltage 31 is applied to the first drift ring 26 closest to the anode 25, the second high voltage 32 is applied to a drift ring 26 closest to the front guard ring 28 at the front side 22. The third high voltage 33 is applied to the radiation window region 27 at the back side 23. The front guard ring 28 and the back guard ring 29 may be connected to ground potential 35 or left floated as described above.

During operation of the semiconductor detector unit 2, i.e. in an intended operation mode 206, a first capacitance C1 is 5 pF, a second capacitance is 5 pF and the third capacitance C3 is 5 pF, for example. Furthermore, during operation of the semiconductor detector unit 2, dominant resistances are a first resistance R1, a second resistance R2 and a third resistance R3. The first resistance R1 is 2 MΩ, the second resistance R2 is for example 10 MΩ, and the third resistance R3 is 100 MΩ, for example. In the operation mode 206, the semiconductor detector module 1 is configured to detect electromagnetic radiation as intended.

In a starting mode 205 of the semiconductor detector mode 1, which is a period between starting the semiconductor detector unit 2 and reaching an operational mode 206, the first capacitance is 5 pF and the second and third capacitances C1, C2 are 10 pF each, for example. Furthermore, in the starting mode 205 dominant resistances are, for example, a fourth resistance R4, a fifth resistance R5 and the third resistance R3. For example, in the starting mode 205 the third resistance R3 is 10 kΩ, the fourth resistance R4 is 200 KΩ and the fifth resistance R5 is 20 KΩ.

During operation, the semiconductor detector unit 2 may require high voltages for operation. For example, the first high voltage 31 is between −10 V and −30 V. Furthermore, the second high voltage 32 is between −110 V and −180 V. The third high voltage 33 is between −50 V and between −100 V. This means that three high voltages 31, 32, 33 have to be provided for operating the semiconductor detector unit 2.

Commonly, these high voltages 31, 32, 33 are externally provided and thus safety requirements for high voltage applications providing voltages above +/−50 V have to be considered. Fulfilling these safety requirements leads to costs during production and limit flexibility in application.

The semiconductor detector module 1 according to the first exemplary embodiment comprises the DC-DC converter unit 3 which is configured to provide the high voltages 31, 32, 33 to the semiconductor detector unit 2, wherein the high voltages 31, 32, 33 are converted from at least one low voltage 30. That is, using the DC-DC converter unit 3 allows the semiconductor detector module 1 to be operated with a low voltage input. Therefore, no high voltage safety requirements need to be considered during production and application of the semiconductor detector module 1.

Referring back to FIG. 1, the DC-DC converter unit 3 is integrated in the housing 10 of the semiconductor detector module 1. In particular, the semiconductor detector unit 2 and the DC-DC converter unit 3 are arranged on opposing sides of a carrier 101. The high voltages are supplied to the semiconductor detector unit 2 via connection wires 104 and a through connection 105.

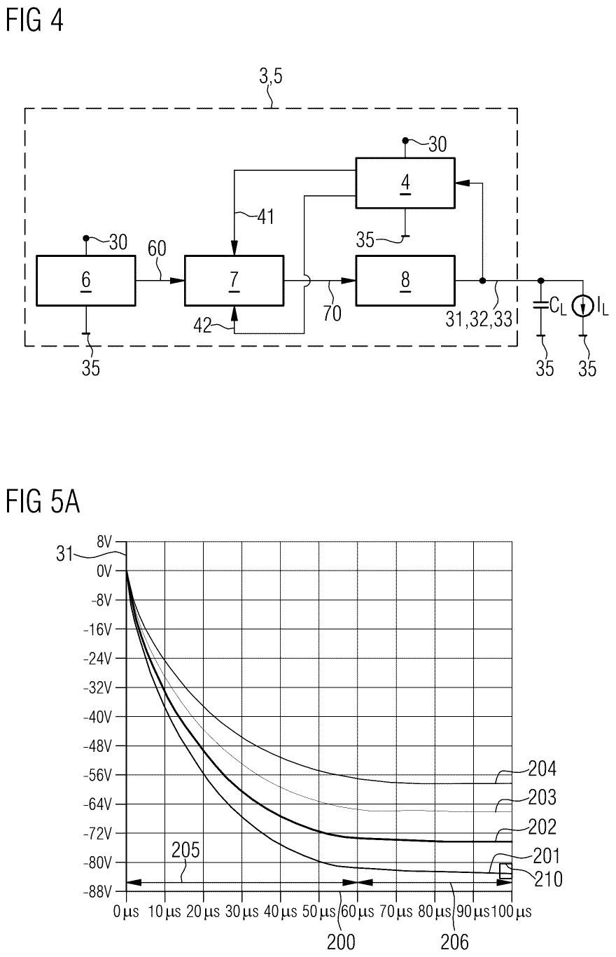

FIG. 4 illustrates a charge pump circuit 5 which is integrated in the DC-DC converter unit 3. The charge pump circuit 5 is configured to convert the low voltage 30 to one of the high voltages 31, 32, 33. In particular, the DC-DC converter unit 3 according to the present exemplary embodiment comprises three charge pump circuits 5 that may be structurally identical with each other. However, individual charge pump circuits 5 may differ in their voltage output such that a first charge pump circuit provides the first high voltage 31, a second charge pump circuit provides the second high voltage 32 and a third charge pump circuit provides the third high voltage 33.

The charge pump circuit 5 comprises an oscillator 6 configured to provide a clock signal 60 and to drive a charge pump 8, a clock buffer 7 configured to amplify the clock signal 60 and to provide an amplified clock signal 70 for the charge pump 8. That is, charge pump 8 is driven by the amplified clock signal 70.

The oscillator 6 comprises a low voltage input at which the low voltage 30 is provided and a ground port at which a ground potential 35 is provided. The charge pump 8 is configured to convert the low voltage 30 to one of the high voltages 31, 32, 33 by means of the amplified clock signal 70.

The charge pump circuit 5 further comprises a regulator 4 which may be supplied with the low voltage 30 and comprises a ground port connected to ground potential 35. The regulator 4 is in particular a PID regulator and provides an upper control voltage 41 and a lower control voltage 42 as supply voltages for the clock buffer 7. Furthermore, the regulator receives the high voltage 31, 32, 33 generated by the charge pump 8 as an input. Thereby, a control loop is established by which the high voltage 31, 32, 33 can be kept at a constant value. This means in particular that the regulator 4 adjusts the upper control voltage 41 and/or the lower control voltage 42 so that a constant value for the high voltage 31, 32, 33 can be achieved.

In particular, amplification of the clock signal 60 performed by the clock buffer 7 is controlled and regulated by the regulator 4 by means of providing the upper control voltage 41 and the lower control voltage 42. Thus, it is advantageously possible to adjust the amplified clock signal 70 driving the charge pump 8 by the regulator such that the high voltage 31, 32, 33 is output with a constant value.

Loads CL, IL may be applied to the charge pump circuit 5. In particular the loads CL, IL comprise a load capacitance CL and a load current IL. The loads CL, IL are determined, for example, by the semiconductor detector unit 2, as illustrated in FIGS. 3A and 3B.

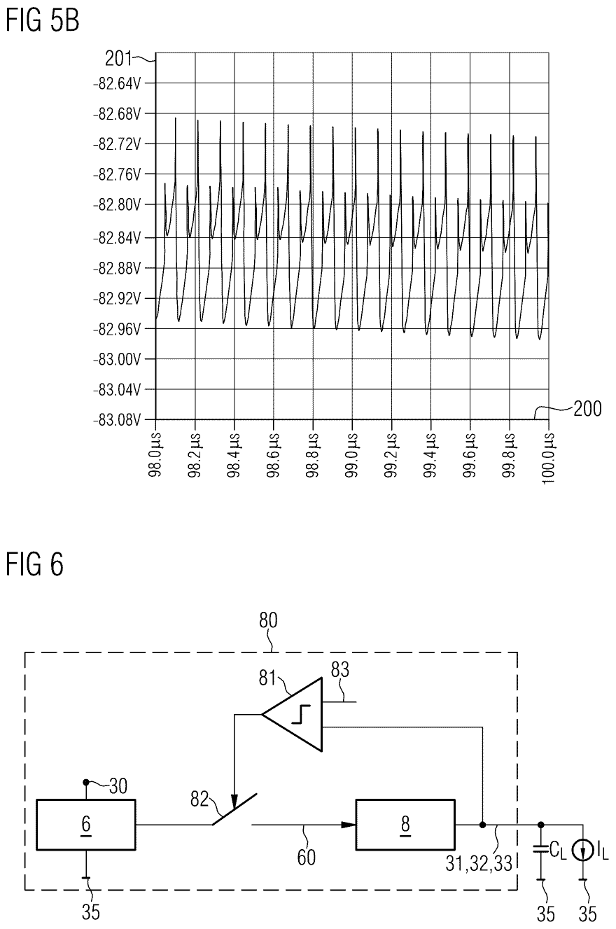

FIGS. 5A and 5B illustrate different output voltages of the charge pump circuit 5, i.e. different values for the first, second or third high voltage 31, 32, 33, for example, as a function of time 200. The curves 201 to 204 correspond to different values of a difference of the upper control voltage 41 and the lower control voltage 42. If the difference between the upper control voltage 41 and the lower control voltage 42 increases, the output voltage 201 to 204 also increases. That is, the constant value of the high voltage 31, 32, 33 can be adjusted by adjusting a difference between the upper control voltage 41 and the lower control voltage 42. It is therefore possible to adjust the constant value of the high voltage 31, 32, 33 if a load CL, IL connected to the charge pump circuit 5 changes, for example due to a temperature drift or the like.

As illustrated in FIG. 5A, the constant values of the voltage outputs 201 to 204 are established after an initial period defining a starting mode 205 of the semiconductor module 1. In particular, during an operation period defining an operation mode 206 of the semiconductor module 1, which follows the starting mode 205, the outputs 201 to 204 are constant. In the starting mode 205, the charge pump 8 is initialized to convert the low voltage 30 to the high voltages 31, 32, 33. The starting mode 205 is terminated if the output of the charge pump 8 reaches the predefined constant values illustrated in FIG. 5A.

In the operation mode 206, the voltage outputs 201 to 204 are constant or essentially constant. In this context “constant” means that the output voltages 201 to 204 comprise variations that are below 1% or below 0.5% of the constant value as illustrated in FIG. 6B showing a detailed view of the curve 201 indicated by reference sign 210 of FIG. 6A.

FIG. 6 shows a modified charge pump circuit 80 according to a comparative example. Compared to the charge pump circuit 5 of FIG. 4, the charge pump circuit 80 of the comparative example comprises a switch 82 connected to a comparator 81 instead of the clock buffer 7 and the regulator 4. The comparator 81 is configured to compare the high voltage 31, 32, 33 provided by the charge pump 8 to a reference voltage 83. If the high voltage 31, 32, 33 falls below the reference potential 83, the switch 82 is closed and if the high voltage 31, 32, 33 exceeds the reference voltage 83, the switch 82 is opened. The comparator 81 comprises a hysteresis which causes an oscillation of the high voltage 31, 32, 33 between two thresholds.

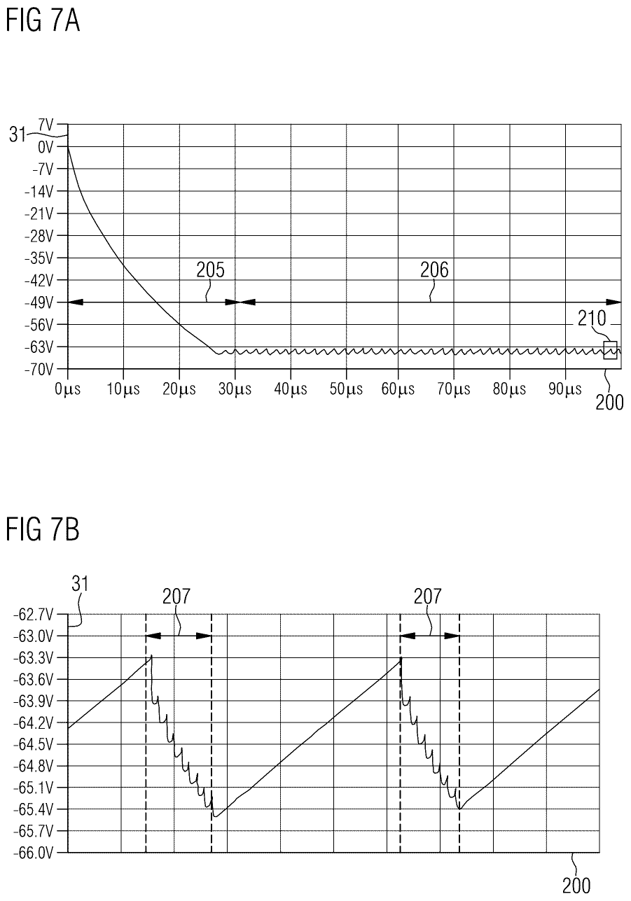

Therefore, an output of the modified charge pump circuit 80 according to the comparative example is not constant as shown in FIGS. 7A and 7B.

In the operation mode 206 following the starting mode 205, the high voltage 31 shows an approximately sawtooth pattern. In the detailed view of FIG. 7B showing a detail indicated by the reference sign 210 in FIG. 7A, pump periods 207 in which the charge pump 8 is active, i.e. the switch 82 is closed, are visible. During the charge pump periods, the high voltage 31 increases from approximately −63.3 V to approximately −65.5 V. After the high voltage 31 reaches this threshold of approximately −65.5 V, the switch 82 is opened and the high voltage slightly decreases to approximately −63.3 V again at which the switch 82 is closed again. These two thresholds are present due to the hysteresis behavior of the comparator 81. Consequently, the high voltage 31 is not as constant as the voltage outputs 201 to 204 of a charge pump circuit 5 described herein as illustrated in FIGS. 5A and 5B.

Since a frequency of the sawtooth pattern of the high voltage 31 of the modified charge pump circuit 80 may interfere with signal processing of the detector signal of the semiconductor detector unit 2, efficiency of the semiconductor module 1 may decrease. That is, by using the charge pump circuit 5 described herein, efficiency and signal quality of the detector signal can be improved.

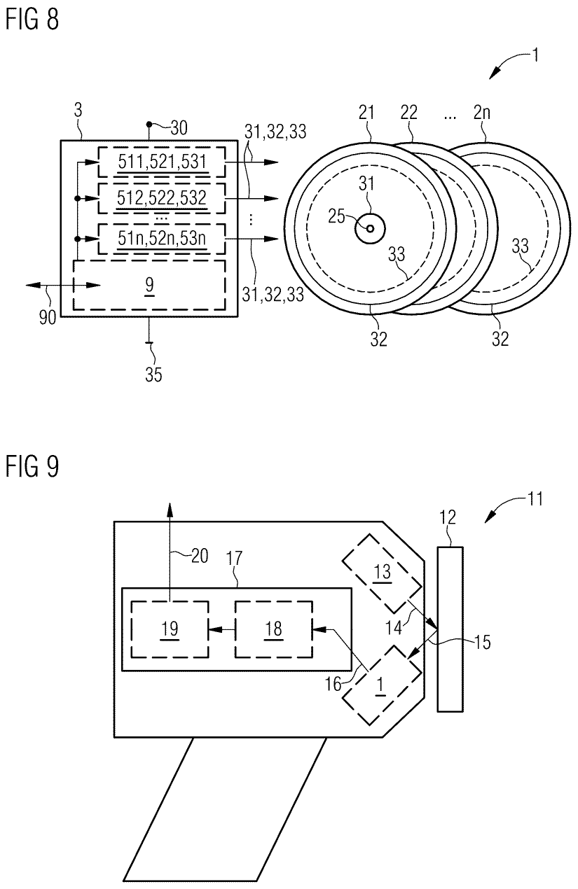

FIG. 8 illustrates a semiconductor module 1 according to a second exemplary embodiment. The semiconductor detector module 1 comprises a plurality of semiconductor detector units 2. That is, the semiconductor detector module 1 according to FIG. 8 comprises a first to an n-th semiconductor detector unit 21 . . . 2n. Each of the semiconductor detector units 21 . . . 2n are configured to be supplied with a first high voltage 31, a second high voltage 32 and a third high voltage 33. In particular, each of the semiconductor detector units 21 . . . 2n may comprise a similar configuration as illustrated in FIG. 2.

The DC-DC converter unit 3 according to the present embodiment comprises a plurality of charge pump circuits 5. In particular, the DC-DC converter unit 3 comprises a plurality of first charge pump circuits 511 . . . 51n, a plurality of second charge pump circuits 52 . . . 52n, and a plurality of third charge pump circuits 531 . . . 53n.

The first charge pump circuits 551 . . . 55n are configured to provide the first voltages 31 for each of the semiconductor detector units 21 . . . 2n. The second charge pump circuits 521 . . . 52n are configured to provide the second high voltage 32 for each of the semiconductor detector units 21 . . . 2n. The third charge pump circuits 531 . . . 53n are configured to provide the third high voltage 33 to each of the semiconductor detector units 21 . . . 2n. Each of the charge pump circuits 511 . . . 51n, 521 . . . 52n, 531 . . . 53n may comprise a configuration similar to the configuration illustrated in FIG. 4.

The DC-DC converter unit 3 may further comprise a control unit 9. The control unit 9 is in particular configured to control the regulator 4 of each of the charge pump circuits 511 . . . 51n, 521 . . . 52n, 531 . . . 53n, for example to adjust the corresponding upper control voltage 41 and the corresponding lower control voltage 42 according to a desired constant value of the high voltage 31, 32, 33.

Furthermore, the control unit 9 may control the oscillator 6 and/or the charge pump circuits 511 . . . 51n, 521 . . . 52n, 531 . . . 53n. Furthermore, the control unit 9 may synchronize the individual charge pump circuits 511 . . . 51n, 521 . . . 52n, 531 . . . 53n.

The control unit 9 may further comprise a data interface for exchanging data 90, by which a communication of the control unit 9 with an external controlling device such as a computer is possible. This allows, for example, to start or determine an operation of the semiconductor detector module 1. Preferably, the data interface is a digital interface.

FIG. 9 illustrates a portable measurement device 11 comprising a semiconductor detector module 1 described herein, for example according to one of the above-mentioned embodiments. The portable measurement device 11 is configured to analyze a sample 12 by means of X-ray fluorescence.

The portable measurement device 11 comprises an X-ray source 13, for example an X-ray tube, configured to irradiate the sample 12 with X-rays 14. The semiconductor detector module 1 is configured to detect fluorescence radiation 15 radiated by the sample 12 in response to being exposed to X-rays 14. Furthermore, a corresponding detector signal 16 is generated by the semiconductor detector module 1 during operation.

The portable measurement device 11 further comprises a calculation unit 17 which comprises a digital signal processor 18 and a central processing unit 19. The digital signal processor 18 is in particular configured to evaluate and analyze the detector signal 16.

A spectrum of the sample 12 may be generated by the central processing unit 19. The results of the measurement evaluated by the calculation unit may be communicated by a data output 20.

The portable measurement device 11 can be supplied with a low voltage 30, for example from a battery, since the semiconductor detector module 1 can be operated with a low voltage by using the DC-DC converter unit 3. Furthermore, the X-ray source 13 may be an X-ray tube comprising a voltage cascade which also may be supplied with the low voltage 30. Thus, it is advantageously possible to form the portable measurement device 11 with a comparable compact housing including a battery or the like. Thus, no complex external voltage supply is necessary, and the portable measurement device 11 can easily be used in different applications.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

What is claimed is:

1. A semiconductor detector module comprising:
at least one semiconductor detector unit; and
a DC-DC converter unit configured to convert a low voltage provided at a low voltage input to a at least one high voltage for the at least one semiconductor detector unit,
wherein the DC-DC converter unit comprises at least one regulator configured to control an output of the DC-DC converter unit and to provide the high voltage with a constant value.

2. The semiconductor detector module according to claim 1, wherein the DC-DC converter unit comprises at least one charge pump circuit, the charge pump circuit comprising:
an oscillator configured to provide a clock signal,
a clock buffer configured to amplify the clock signal,
the regulator configured to provide an upper control voltage and a lower control voltage as supply voltages to the clock buffer, and
at least one charge pump configured to convert the low voltage into high voltage, and
wherein the regulator is configured to adjust the upper control voltage and the lower control voltage such that the charge pump provides the high voltage with the constant value.

3. The semiconductor detector module according to claim 2, wherein the regulator is configured to adjust the value of the high voltage by adjusting a difference between the upper control voltage and the lower control voltage.

4. The semiconductor detector module according to claim 3, further comprising a control unit configured to control the regulator to adjust the value of the high voltage according to a load connected to the charge pump circuit.

5. The semiconductor detector module according to claim 4, wherein the control unit is further configured to:
adjust the upper control voltage and the lower control voltage (in accordance with the value of the high voltage determined according to the load,
adjust a frequency of the oscillator, and/or
control and/or synchronize a plurality of charge pump circuits.

6. The semiconductor detector module according to claim 2, wherein the at least one semiconductor unit comprises exactly one semiconductor detector unit configured to be supplied with three high voltages, and
wherein the DC-DC converter unit comprises a first charge pump circuit, a second charge pump circuit, and a third charge pump circuit configured to provide a first high voltage, a second high voltage and a third high voltage, respectively.

7. The semiconductor detector module according to claim 2, wherein the at least one semiconductor detector unit comprises a plurality of semiconductor detector units, each configured to be supplied with three high voltages,
wherein the DC-DC converter unit comprises a plurality of first charge pump circuits (, a plurality of second charge pump circuits, and a plurality of third charge pump circuits, configured to supply a first high voltage, a second high voltage, and a third high voltage, respectively, to each of the semiconductor detector units.

8. The semiconductor detector module according to claim 7, further comprising:
a control unit configured to adjust each of the first, second, and third high voltages according to a corresponding load determined by an assigned semiconductor detector unit.

9. The semiconductor detector module according to claim 1, wherein the at least one semiconductor detector unit and the DC-DC converter unit are integrated in a common module housing, and wherein the semiconductor detector module is externally exclusively electrically suppliable by the low voltage.

10. The semiconductor detector module according to claim 1, wherein the at least one semiconductor detector unit and the DC-DC converter unit are arranged in distinct housings, and wherein the semiconductor detector module is externally exclusively electrically suppliable by the low voltage.

11. The semiconductor detector module according to claim 1,
wherein each semiconductor detector unit comprises a silicon drift detector,
wherein each regulator is configured to operate as a PID regulator, and
wherein the DC-DC converter unit is an application-specific integrated circuit (ASIC).

12. A charge pump circuit comprising:
an oscillator configured to provide a clock signal;
a clock buffer configured to amplify the clock signal;
a regulator configured provide an upper control voltage and a lower control voltage as supply voltages to the clock buffer; and
at least one charge pump configured to convert a low voltage to a high voltage,
wherein the regulator is configured to adjust the upper control voltage and the lower control voltage such that the charge pump is configured to provide the high voltage with a constant value.

13. The charge pump circuit according to claim 12, wherein the regulator is configured to adjust the value of the high voltage by adjusting a difference between the upper control voltage and the lower control voltage.

14. The charge pump circuit according to claim 12, further comprising or coupled to a control unit configured to control the regulator to adjust the value of the high voltage according to a load connectable to an output of the charge pump circuit.

15. The charge pump circuit according to claim 14, wherein the charge pump circuit and the control unit are integrated in a single electronic component having a data interface and a single low voltage input.

16. A portable measurement device comprising:
an X-ray source configured to irradiate a sample with X-rays;
the semiconductor detector module according to claim 1 and configured to detect fluorescence radiation radiated by the sample in response to being exposed to the X-rays and to generate a corresponding detector signal; and
a calculation unit comprising a digital signal processor configured to analyze the detector signal to measure the sample.
